(19) United States
(12) Patent Application Publication
(10) Pub. No.: US 2013/0082779 A1
(43) Pub. Date: Apr. 4, 2013

(54) AMPLIFIER

(71) Applicant: Shigeru SAITO, Kanagawa (JP)

(72) Inventor: Shigeru SAITO, Kanagawa (JP)

(73) Assignee: Renesas Electronics Corporation

(21) Appl. No.: 13/544,692

(22) Filed: Jul. 9, 2012

(30) Foreign Application Priority Data
Sep. 29, 2011 (JP) 2011-214181

(51) Int. Cl. H03F 3/16

(52) U.S. Cl. 330/277

(57) ABSTRACT

To suppress the occurrence of distortion. There are included an initial-stage amplifier circuit PREA that receives an input signal IN, a first source-grounded transistor Tr1 that receives an output signal of the initial-stage amplifier circuit PREA at the gate, a second gate-grounded transistor Tr2 the source of which is coupled to the drain of the first transistor Tr1, which sends out an output signal OUT from the drain and at the same time, to the drain of which, a power source is supplied, and a first impedance circuit Z1 interposed between a power source end of the initial-stage amplifier circuit PREA and the source of the second transistor Tr2. The first impedance circuit Z1 is a circuit configured so as to cause a direct current to pass and at the same time, to have an impedance equal to or higher than a predetermined impedance in a predetermined frequency band.

### CROSS-REFERENCE TO RELATED APPLICATION

The disclosure of Japanese Patent Application No. 2011-214181 filed on Sep. 29, 2011 including the specification, drawings and abstract is incorporated herein by reference in its entirety.

### BACKGROUND

The present invention relates to an amplifier and, more particularly, to a wideband amplifier of high-frequency signals of CATV etc.

An amplifier of multi-signals of CATV etc. is required to be excellent in the wideband characteristics and low distortion characteristics. To respond to such a request, a cascode circuit is used generally, in which a source-grounded transistor is used as a previous stage and a gate-grounded transistor as a post stage and both transistors are coupled in cascade. In the cascode circuit, transistors in two stages are coupled directly and when it is necessary to further increase gain, an amplifier circuit in the initial stage is further coupled ahead of the transistor in the previous stage. Examples of such an amplifier are disclosed in Japanese Patent No. 2848449 (Patent Document 1) and in Japanese Patent Laid-Open No. 2003-198276 (Patent Document 2).

FIGS. 6A and 6B are circuit diagrams of a wideband amplifier described in Patent Document 1 and FIG. 6A shows an AC equivalent circuit and FIG. 6B shows a DC equivalent circuit.

Referring to an AC equivalent circuit shown in FIG. 6A, an amplifier in the first stage includes an FET 31 and a source resistor Ra1 and one end of the source resistor Ra1 is coupled to the source of the FET 31 and the other end is grounded. A first negative feedback circuit 26 includes a capacitor C1 and a resistor R1 and is coupled between the source and the drain of the FET 31. Amplifiers in the second stage and in the third stage include FETs 32 and 33, a source resistor Ra2, and a gate resistor Ra3 and the FETs 32 and 33 are cascode-coupled and one end of the source resistor Ra2 is coupled to the source of the FET 32 and the other end is grounded. Furthermore, one end of the gate resistor Ra3 is coupled to the gate of the FET 33 and the other end is grounded. A second negative feedback circuit 27 includes a capacitor C2 and a resistor R2 and is coupled between the drain of the FET 33 and the gate of the FET 32. Furthermore, in FIG. 2A, a load L is coupled between an output terminal OUT and the ground.

In FIG. 6B, resistors R5, R52, and R53 are configured in order to give a gate bias to the FET 33 and similarly, resistors R6, R61, and R62 are configured in order to give a gate bias to the FET 32, and resistors R63 and R64 are configured in order to supply a gate bias to the FET 31. A resistor R31 coupled to the source of the FET 31 is configured in order to determine a gate bias. Except for the resistor R31, an electric current for these biases is about 1/100 of an electric current flowing through FET, and thus, hardly affects power consumption. A resistor R41 coupled to the source of the FET 32, a capacitor C6, and an inductor L2 configure a filter circuit to prevent an AC signal from returning to the previous stage and a capacitor C5 coupled between the drain of the FET 31 and the gate of the FET32 is a capacitor to block a direct current.

By designing the configuration as that shown in FIGS. 6A and 6B, it is possible to reduce the number of paths of electric currents flowing through the FETs 31 to 33 to one without causing an electric current to flow through each stage in parallel, and thus it is possible to reduce the circuit current to ½ to ⅓ compared with the current flowing through each stage in parallel. Furthermore, the FETs 31 to 33 are coupled in series in terms of DC, and thus it is possible to increase the withstand voltage of the whole circuit in which each FET is coupled in series even if the withstand voltage of each FET is low, and as a result, even if a high DC voltage of about 24 V is applied to a power source terminal VDD, the circuit is not broken.

In addition, in Patent Document 2, a wideband amplifier is disclosed, which includes two cascode circuits coupled in cascade in terms of AC and coupled in series in terms of DC.

### SUMMARY

The following analyses will be given in the present invention.

In a conventional wideband amplifier, an amplifying device in each stage is coupled in cascade in terms of AC and gain is increased in terms of high frequency. In contrast, in terms of DC, all the amplifying devices in each stage are coupled in series, and thus the drain-source voltage to be applied to each amplifying device is a value into which the power source voltage is divided. Consequently, when the number of amplifying devices coupled in series increases, the drain-source voltage is reduced.

Here, in the case of cascode coupling including, for example, only two stages, it is a general practice to apply as high a voltage as possible to the output stage to thereby increase the saturation output, and to set the bias of the amplifier circuit in the previous stage to a voltage by which an output capable of sufficiently driving the output stage is obtained. If the drain-source voltage in the initial stage of the two-stage cascode circuit is set to be V1, a drain-source voltage V2 that can be applied to the output stage is expressed as follows. V2=Vdd−V1−Vs, where Vdd is a power source voltage and Vs is a source potential of the initial stage of the cascode circuit.

Incidentally, if a one-stage source-grounded circuit is added to the input side of the cascode circuit in order to increase gain as in Patent Document 1, the drain-source voltage is necessary also in the amplifying device of the source-grounded circuit. If a drain-source voltage to be added is set to be V1′, a drain-source voltage V2′ of the output stage is reduced compared with V2 as shown below. V2′=Vdd−V1−V1′−Vs.

As described above, the drain-source voltage of the output stage is reduced by the value of the drain-source voltage used in the added amplifier circuit in the initial stage, and thus the saturation output power of the output stage is reduced. This is the same in the case of Patent Document 2 and as the number of element stages increases, the saturation output voltage of the output stage is furthermore reduced by an amount corresponding to the increase in the number of element stages. Then, there is a possibility that such a reduction in the saturation output voltage increases signal distortion in the amplifier.

Furthermore, the saturation output voltage is reduced in proportion to the square of the applied voltage, and thus it is important to keep the saturation output power by increasing the drain-source voltage. If the amount of reduction in power is taken to be ΔP, ΔP is approximated by the following expression and the power is reduced. ΔP=10 log(V2′/V2)̂2 (dB).

An amplifier according to an aspect of the present invention includes an initial-stage amplifier circuit that receives an input signal, a first source-grounded transistor that receives an output signal of the initial-stage amplifier circuit at the gate, a second gate-grounded transistor the source of which is coupled to the drain of the first transistor and which sends out an output signal from the drain and at the same time, to the drain of which, a power source is supplied, and a first impedance circuit interposed between the power source end of the initial-stage amplifier circuit and the source of the second transistor. The first impedance circuit is a circuit configured so as to cause a direct current to pass and at the same time, to have an impedance equal to or higher than a predetermined impedance in a predetermined frequency band.

According to the present invention, it is possible to lower the occurrence of distortion in an output signal.

### BRIEF DESCRIPTION OF THE DRAWINGS

FIG. 1 is a circuit diagram of an amplifier according to a first embodiment of the present invention;

FIGS. 2A to 2F are circuit diagrams of an impedance circuit according to the first embodiment of the present invention;

FIG. 3 is a circuit diagram of an initial-stage amplifier circuit according to the first embodiment of the present invention;

FIG. 4 is a circuit diagram of an initial-stage amplifier circuit according to a second embodiment of the present invention;

FIG. 5 is a circuit diagram of an initial-stage amplifier circuit according to a third embodiment of the present invention; and

FIGS. 6A and 6B are circuit diagrams of a conventional amplifier.

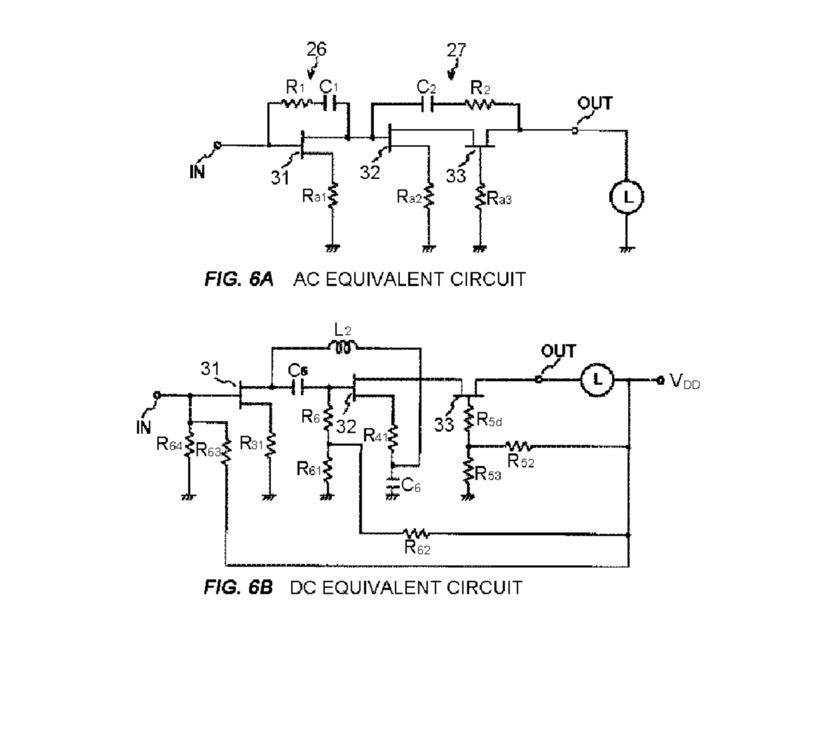

### DETAILED DESCRIPTION

Hereinafter, embodiments for embodying the present invention will be outlined. It should be noted that reference symbols of the drawings attached to the following outline are merely illustrations to help understanding and are not intended to be limited to the aspects shown schematically.

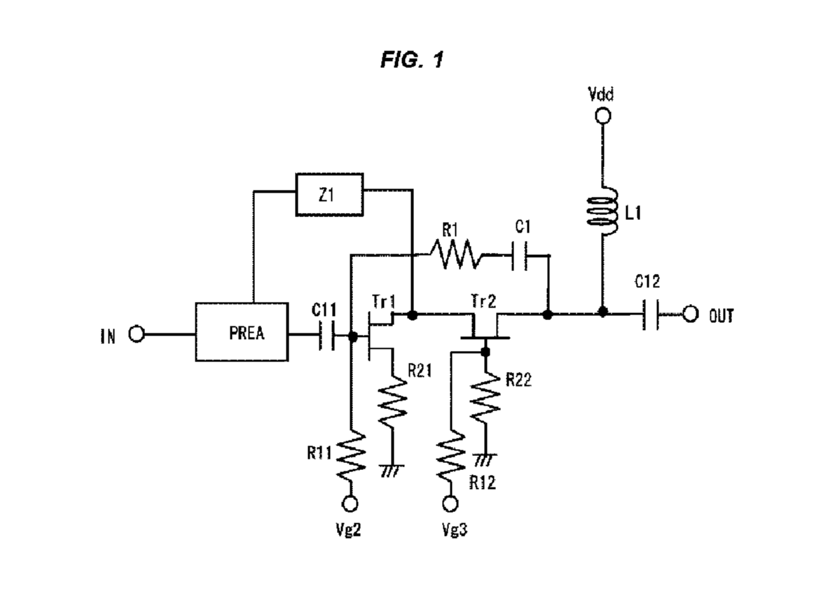

An amplifier according to an embodiment of the present invention includes an initial-stage amplifier circuit (PREA in FIG. 1) that receives an input signal (IN in FIG. 1), a first source-grounded transistor (Tr1 in FIG. 1) that receives an output signal of the initial-stage amplifier circuit at the gate, a second gate-grounded transistor (Tr2 in FIG. 1) the source of which is coupled to the drain of the first transistor and which sends out an output signal (OUT in FIG. 1) from the drain and at the same time, to the drain of which, a power source is supplied, and a first impedance circuit (Z1 in FIG. 1) interposed between a power source end of the initial-stage amplifier circuit and the source of the second transistor. The first impedance circuit is a circuit configured so as to cause a direct current to pass and at the same time, to have an impedance equal to or higher than a predetermined impedance in a predetermined frequency band.

In such an amplifier as described above, gain of the amplifier is improved by adding an initial-stage amplifier circuit to the previous stage. The power source end of the initial-stage amplifier circuit is coupled to the source of the second transistor serving as an output stage of a cascode circuit via the first impedance circuit that causes a direct current to pass. Consequently, the power source current in the initial-stage amplifier circuit increases the drain current of the second transistor and it is possible to lower the occurrence of distortion in the second transistor.

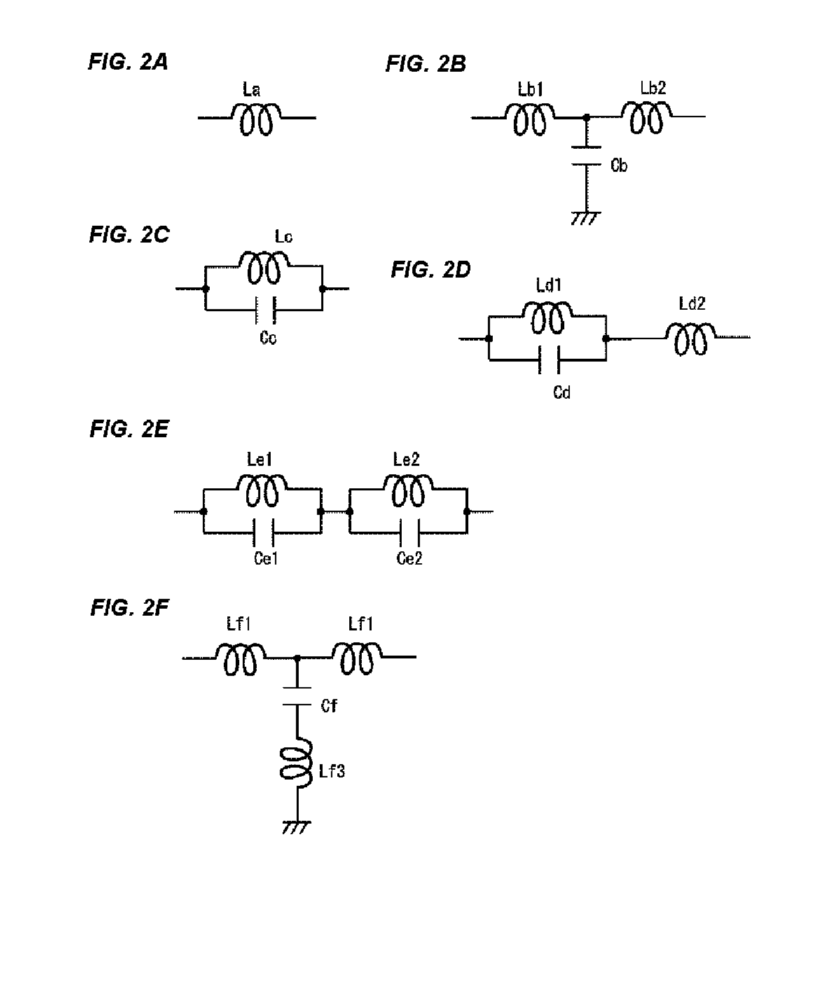

In the amplifier, it is preferable for the first impedance circuit to include an inductor (for example, La in FIG. 2A) in a path between one end and the other end.

In the amplifier, the first impedance circuit may be a circuit including a serially coupled circuit including two inductors (Lb1 and Lb2 in FIG. 2B) in a path between one end and the other end and a capacitor (Cb in FIG. 2B) between the coupling point of the two inductors and the ground.

In the amplifier, the first impedance circuit may include a parallelly coupled circuit of an inductor and a capacitor (for example, Lc and Cc in FIG. 2C) in a path between one end and the other end.

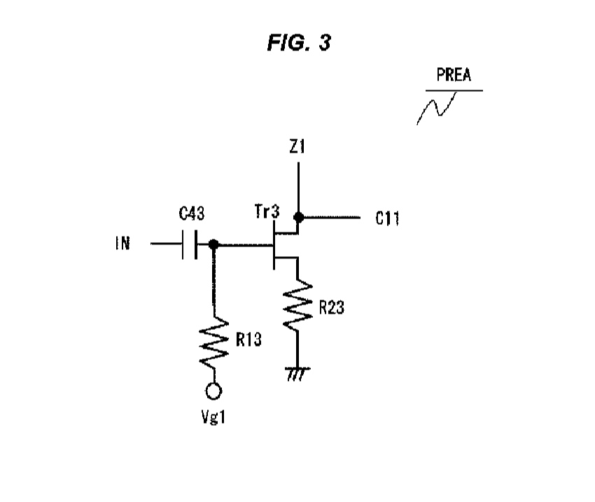

In the amplifier, the initial-stage amplifier circuit may include a third transistor (Tr3 in FIG. 3) the source of which is grounded and the power source end and the output end of the initial-stage amplifier circuit may be coupled together to the drain of the third transistor.

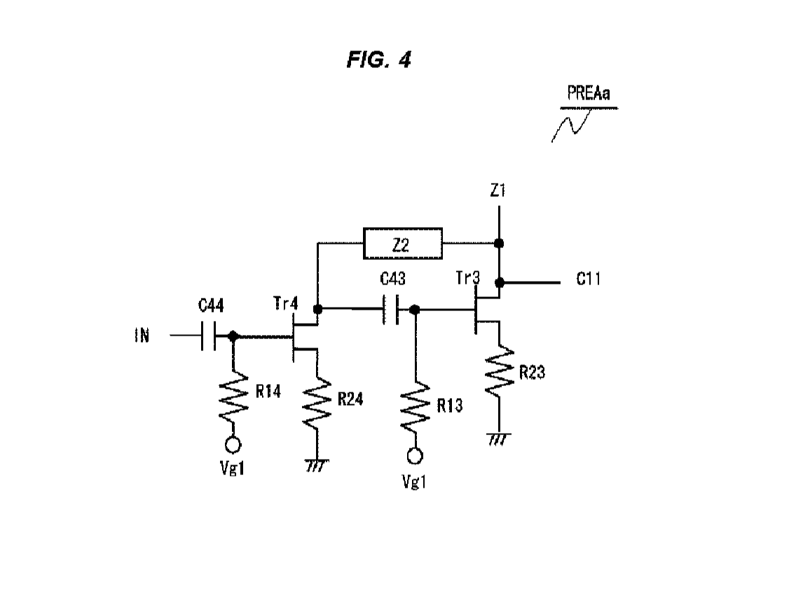

In the amplifier, the initial-stage amplifier circuit may be a circuit further including a fourth source-grounded transistor (Tr4 in FIG. 4) that receives an input signal at the gate and a second impedance circuit (Z2 in FIG. 4) and configured so that the drain of the fourth transistor is coupled to the gate of the third transistor and at the same time, is coupled to the drain of the third transistor via the second impedance circuit and the second impedance circuit allows a direct current to pass and at the same time, has an impedance equal to or higher than a predetermined impedance in a predetermined frequency band.

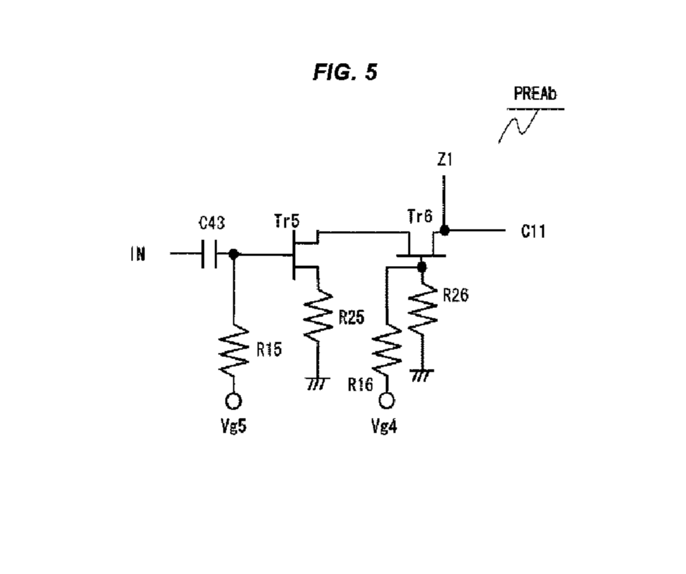

In the amplifier, the initial-stage amplifier circuit may include a cascode circuit (Tr5 and Tr6 in FIG. 5) and the power source end and the output end of the initial-stage amplifier circuit may be coupled together to the output end of the cascode circuit.

In the amplifier, it is preferable at least for the second transistor to be a high-electron-mobility transistor.

In the amplifier, the high-electron-mobility transistor may be a gallium nitride field-effect transistor.

Hereinafter, embodiments are explained in detail with reference to the drawings.

### First Embodiment

FIG. 1 is a circuit diagram of an amplifier according to a first embodiment of the present invention. In FIG. 1, the amplifier includes an initial-stage amplifier circuit PREA, field-effect transistors Tr1 and Tr2, an impedance circuit Z1, resistive elements R1, R11, R12, R21, and R22, capacitive elements C1, C11, and C12, and an inductor L1.

The initial-stage amplifier circuit PREA operates on a power source supplied via the impedance circuit Z1 and receives an input signal IN and supplies an amplified output signal to the gate of the field-effect transistor Tr1 via the capacitive element C11.

The source of the field-effect transistor Tr1 is grounded via the resistive element R21 and to the gate, a bias voltage Vg2 is supplied via the resistive element R11 (source grounded) and the drain is coupled to the source of the field-effect transistor Tr2.

The gate of the field-effect transistor Tr2 is grounded via the resistive element R22 and at the same time, to the gate, a bias voltage Vg3 is supplied via the resistive element R12 (gate grounded) and the source is coupled to the drain of the field-effect transistor Tr1 and at the same time, the field-effect transistor Tr2 supplies a power source to the initial-stage amplifier circuit PREA via the impedance circuit Z1, and the drain is coupled to one end of the capacitive element C1 and to one end of the inductor L1 and at the same time, the field-effect transistor Tr2 outputs an output signal OUT from the drain via the capacitive element C12. To the other end of the inductor L, a power source voltage Vdd is supplied.

The field-effect transistor Tr2 as described above configures a cascode circuit together with the field-effect transistor Tr1. The resistive element R21 supplies the field-effect transistor Tr1 with a source potential (Vs) to use the field-effect transistor Tr1 on a single power source. Vg2 is applied to the gate of the field-effect transistor Tr1 via the resistive element R11 to set a drain current of the field-effect transistor Tr1. The gate of the field-effect transistor Tr2 is grounded by the resistive element R22 and Vg3 is applied to the gate of the field-effect transistor Tr2 via the resistive element R12 to set a source potential of the field-effect transistor Tr2.

The other end of the capacitive element C1 is coupled to the gate of the field-effect transistor Tr1 via the resistive element R1 to configure a feedback circuit of the cascode circuit for extending the operation band together with the resistive element R1.

The impedance circuit Z1 is a circuit configured so as to cause a direct current to pass and at the same time, to have an impedance equal to or higher than a predetermined impedance in a predetermined frequency band. The impedance circuit Z1 functions as a power source supply path for the initial-stage amplifier circuit PREA and has a function to cut off a high-frequency signal.

Next, an example of a more specific circuit of the impedance circuit Z1 will be explained. FIGS. 2A to 2F are examples of a circuit diagram of the impedance circuit Z1. Here, a capacitive element is referred to as a capacitor. In FIG. 2A, the impedance circuit Z1 includes an inductor La.

In FIG. 2B, the impedance circuit Z1 is a low-pass filter including a serially coupled circuit including two inductors Lb1 and Lb2 and including a capacitor (capacitive element) Cb between the coupling point of the two inductors Lb1 and Lb2 and the ground. It is possible to realize desired filter characteristics by optimally setting the constants of L and C in the circuit in FIG. 2B. Furthermore, by configuring a multi-stage LC filter, it is also possible to further enhance the effect of reducing a high-frequency signal. According to the impedance circuit Z1 as described above, the possibility of the occurrence of oscillation caused by sneaking of a signal is suppressed.

In FIG. 2C, the impedance circuit Z1 includes a parallelly coupled circuit of an inductor Lc and a capacitor Cc. In FIG. 2D, the impedance circuit Z1 includes a circuit in which an induction Ld2 is further coupled in series to a parallelly coupled circuit of an inductor Ld1 and a capacitor Cd. In FIG. 2E, the impedance circuit Z1 includes a circuit in which a parallelly coupled circuit of an inductor Le1 and a capacitor Ce1 and a parallelly coupled circuit of an inductor Le2 and a capacitor Ce2 are coupled in series. In FIG. 2F, the impedance circuit Z1 is a low-pass filter including a serially coupled circuit of two inductors Lf1 and Lf2 and including a series circuit of a capacitor Cf and an inductor Lf3 between the coupling point of the two inductors Lf1 and Lf2 and the ground.

Here, the impedance circuit Z1 shown in FIGS. 2C to 2E includes a parallel circuit of LC and have a pole at the resonance frequency of LC. The impedance circuit Z1 shown in FIG. 2F includes a series circuit of LC and has a zero point at the resonance frequency of LC. These circuits have the function to block a high-frequency signal near the resonance frequency, respectively. Consequently, in particular, the impedance circuit Z1 shown in FIGS. 2C and 2E includes only the parallel resonance circuit and is effective when being caused to function as a power source supply path corresponding to a narrow band signal.

Meanwhile, although not shown schematically in FIGS. 2A to 2F, the configuration may be such that a resistive element is added to the inductor in series or in parallel as necessary. By adding a resistive element, it is possible to further enhance the effect of reducing signal propagation. That is, by using a resistive element, it is possible to reduce a high-frequency signal that leaks via the impedance circuit Z1 more than when an inductor alone is used, and it is possible to realize a stable circuit that suppresses oscillation caused by leakage. Furthermore, in FIGS. 2C and 2E in particular, by adding a resistive element, it is possible to reduce Q of the resonance circuit and to widen the signal band.

Next, the initial-stage amplifier circuit PREA will be explained. FIG. 3 is a circuit diagram of the initial-stage amplifier circuit according to the first embodiment of the present invention. In FIG. 3, the initial-stage amplifier circuit PREA includes a field-effect transistor Tr3, resistive elements R13 and R23, and a capacitive element C43.

The drain of the field-effect transistor Tr3 is coupled to one end of the impedance circuit Z1 and to one end of the capacitive element C11 and receives the input signal IN at the gate via the capacitive element C43 and at the same time, to the gate, a bias voltage Vg1 is supplied via the resistive element R13 and the source is grounded via the resistive element R23, and thus, the field-effect transistor Tr3 functions as a source-grounded amplifier circuit.

From the source of the field-effect transistor Tr2, a power source is supplied to the drain of the field-effect transistor Tr3 via the impedance circuit Z1 and to the source of the field-effect transistor Tr3, a source potential (Vs′) is given by the resistive element R23. Vg1 is applied to the gate of the field-effect transistor Tr3 via the resistive element R13 to set a drain current of the field-effect transistor Tr3. Consequently, in FIG. 1, the drain current of the field-effect transistor Tr2 is the sum of each drain current of the field-effect transistors Tr1 and Tr3.

The high-frequency signal applied to the input IN is amplified in the field-effect transistors Tr3 and input to the two-stage amplifier of the cascode circuit via the capacitor C11. At this time, the impedance between the drain of the field-effect transistor Tr3 and the drain of the field-effect transistor Tr2 becomes high because of the impedance circuit Z1, and thus propagation of the high-frequency signal is blocked. Consequently, the amplifier functions as an amplifier circuit with a three-stage configuration.

It may also be possible to include a matching circuit with outside before and after the amplifier in FIG. 1 if necessary. Although not shown schematically in FIG. 3, it may also be possible to include a feedback circuit (corresponding to the negative feedback circuit 26 in Patent Document 1) etc. of the field-effect transistor Tr3.

As described above, in the amplifier of the present embodiment, the drain current of the field-effect transistor Tr2 is a current, which is the sum of the drain current of the field-effect transistor Tr1 and the drain current of the field-effect transistor Tr3 added to increase gain. The field-effect transistors Tr1 and Tr3 have a parallel configuration in terms of DC and are coupled in cascade in terms of high frequency. Furthermore, the field-effect transistors Tr1 and Tr3 are in a relationship of series coupling in terms of DC for the field-effect transistors Tr2.

The level of the high-frequency signal of the field-effect transistor Tr3 is lower than that of the field-effect transistor Tr1, and thus the saturation output voltage may be lower by an amount corresponding to the gain of the cascode coupling. Consequently, the drain-source voltage of the field-effect transistor Tr3 does not cause any problem even if the field-effect transistor Tr3 is operated on a low voltage. Furthermore, even if the operation current is reduced less than that of the field-effect transistor Tr2, distortion occurs very slightly.

The field-effect transistors Tr1 and Tr3 are coupled in parallel in terms of DC, and thus a source-drain voltage (V2) of the field-effect transistor Tr2 is smaller than the power source voltage Vdd by an amount corresponding to the drain-source voltage (V1) of the field-effect transistors Tr1 and Tr3. This is approximately the same as the drain-source voltage in the case of the two-stage configuration. V2=Vdd−V1−Vs, where V1 is the drain-source voltage of the field-effect transistors Tr1 and Tr3.

In the case of the CATV trunk network in which such an amplifier is used, the power source voltage Vdd is about 24 V and the operation voltage is too high for MESFET etc. and the withstand voltage of the transistor causes a problem. Consequently, the circuit in which all components are coupled in series in terms of DC as shown in the conventional example is used.

In contrast to this, in the present embodiment, as the field-effect transistor Tr2 in particular, a high-electron-mobility transistor (HEMT), for example, a high withstand-voltage gallium nitride field-effect transistor (GaNFET) is used, and thereby, the voltage drop is small and a high voltage operation is enabled.

As explained above, it is possible for the three-stage amplifier of the present embodiment to operate on approximately the same voltage as the drain-source voltage of the field-effect transistor Tr2 in the output stage in the case of the two-stage configuration. The drain current of the field-effect transistor Tr3 that is added increases the drain current of the field-effect transistor Tr2 in the output stage of cascode coupling. Consequently, gain in the amplifier is improved and at the same time, it is possible to further reduce distortion of the output signal.

As described above, the configuration is explained, in which the first-stage amplifying device is added as the initial-stage amplifier circuit PREA, but a configuration in which amplifying devices in a plurality of stages are added as an initial-stage amplifier circuit is also possible. Hereinafter, an embodiment relating to this will be explained.

### Second Embodiment

FIG. 4 is a circuit diagram of an initial-stage amplifier circuit according to a second embodiment of the present invention. In FIG. 4, the same symbol as that in FIG. 3 represents the same component and its explanation is omitted. An initial-stage amplifier circuit PREAa in FIG. 4 further includes a field-effect transistor Tr4, an impedance circuit Z2, resistive elements R14 and R24, and a capacitive element C44 in addition to the components in FIG. 3.

The drain of the field-effect transistor Tr4 is coupled to the drain of the field-effect transistor Tr3 via the impedance circuit Z2 and at the same time, coupled to the gate of the field-effect transistor Tr3 via the capacitive element C43, and receives the input signal IN at the gate via the capacitive element C44 and at the same time, to the gate, the bias voltage Vg1 is supplied via the resistive element R14 and the source is grounded via the resistive element R24, and thus, the field-effect transistor Tr4 functions as a source-grounded amplifier circuit.

The impedance circuit Z2 is configured to have the same configuration as that of the impedance circuit Z1 explained in the first embodiment and has the function to cut off a high-frequency signal as a power source supply path for the field-effect transistor Tr4.

In the initial-stage amplifier circuit PREAa with such a configuration, to the field-effect transistor Tr4, the power source approximately the same as that of the field-effect transistor Tr3 is supplied via the impedance circuit Z2. Consequently, the initial-stage amplifier circuit PREAa is configured as an amplifier circuit including a two-stage configuration of the field-effect transistors Tr4 and Tr3, which are each a source-grounded transistor, and a higher gain compared with that of the initial-stage amplifier circuit PREA in FIG. 3 is obtained.

### Third Embodiment

FIG. 5 is a circuit diagram of an initial-stage amplifier circuit according to a third embodiment of the present invention. In FIG. 5, the same symbol as that in FIG. 3 represents the same component and its explanation is omitted. An initial-stage amplifier circuit PREAb in FIG. 5 includes field-effect transistors Tr5 and Tr6, resistive elements R15, R16, R25, and R26, and the capacitive element C43.

The source of the field-effect transistor Tr5 is grounded via the resistive element R25 and to the gate, a bias voltage Vg5 is supplied via the resistive element R15 (source grounded) and at the same time, the input signal IN is given via the capacitive element C43 and the drain is coupled to the source of the field-effect transistor Tr6.

The gate of the field-effect transistor Tr6 is grounded via the resistive element R26 and at the same time, to the gate, a bias voltage Vg6 is supplied via the resistive element R16 (gate grounded), the source is coupled to the drain of the field-effect transistor Tr5, and the drain is coupled to one end of the capacitive element C11 and to one end of the inductor L1. The field-effect transistor Tr6 as described above configures a cascode circuit together with the field-effect transistor Tr5.

Consequently, in the initial-stage amplifier circuit PREAb including a cascode circuit, a higher gain is obtained compared with that in the initial-stage amplifier circuit PREA in FIG. 3.

Meanwhile, in FIGS. 4 and 5, the feedback circuit corresponding to the negative feedback circuit 26 in Patent Document 1 is omitted, but it may also be possible to include the feedback circuit as necessary.

Furthermore, in the above explanation, with respect to the field-effect transistors Tr1 to Tr6, it may also be possible to use a bipolar transistor that replaces drain, gate, and source with collector, base, and emitter, respectively.

Each disclosure of the previously described Patent Documents etc. is incorporated in the present specification by reference. In the scope of all the disclosures (including the scope of claims) of the present invention, it is possible to alter/adjust the embodiments and examples based on the basic technical idea thereof. Furthermore, in the scope of claims of the present invention, it is possible to variedly combine and select the various disclosed elements. That is, it is needless to say that the present invention includes various alterations and modifications that should be done by persons skilled in the art in accordance with all the disclosures including the scope of claims and the technical idea.

What is claimed is:

1. An amplifier comprising:
an initial-stage amplifier circuit that receives an input signal;
a first source-grounded transistor that receives an output signal of the initial-stage amplifier circuit at the gate;
a second gate-grounded transistor the source of which is coupled to the drain of the first transistor and which sends out an output signal from the drain and at the same time, to the drain of which, a power source is supplied; and
a first impedance circuit interposed between a power source end of the initial-stage amplifier circuit and the source of the second transistor,
wherein the first impedance circuit is a circuit configured so as to cause a direct current to pass and at the same time, so as to have an impedance equal to or higher than a predetermined impedance in a predetermined frequency band.

2. The amplifier according to claim 1,
wherein the first impedance circuit includes an inductor in a path between one end and the other end.

3. The amplifier according to claim 1,
wherein the first impedance circuit is a circuit including a serially coupled circuit including two inductors in a path between one end and the other end, and including a capacitor between the coupling point of the two inductors and the ground.

4. The amplifier according to claim 1,
wherein the first impedance circuit includes a parallelly coupled circuit of an inductor and a capacitor in a path between one end and the other end.

5. The amplifier according to claim 1,
wherein the initial-stage amplifier circuit includes a third source-grounded transistor, and a power source end and an output end of the initial-stage amplifier circuit are together coupled to the drain of the third transistor.

6. The amplifier according to claim 5,
wherein the initial-stage amplifier circuit further includes a fourth source-grounded transistor that receives the input signal at the gate and a second impedance circuit,
wherein the drain of the fourth transistor is coupled to the gate of the third transistor and at the same time, coupled to the drain of the third transistor via the second impedance circuit, and
wherein the second impedance circuit is a circuit configured so as to cause a direct current to pass and at the same time, so as to have an impedance equal to or higher than a predetermined impedance in a predetermined frequency band.

7. The amplifier according to claim 1,
wherein the initial-stage amplifier circuit includes a cascode circuit, and a power source end and an output end of the initial-stage amplifier circuit are together coupled to an output end of the cascode circuit.

8. The amplifier according to claim 1,
wherein at least the second transistor is a high-electron-mobility transistor.

9. The amplifier according to claim 8,
wherein the high-electron-mobility transistor is a gallium nitride field-effect transistor.
